(19) United States
(12) Patent Application Publication
(10) Pub. No.: US 2026/0328841 A1
(43) Pub. Date: Oct. 22, 2026

(54) SEMICONDUCTOR DEVICE INCLUDING TRANSMISSION CIRCUIT AND OPERATING METHOD OF THE SEMICONDUCTOR DEVICE

(71) Applicants: Samsung Electronics Co., Ltd., Suwon-si (KR); Uif (University Industry Foundation), Yonsei University, Seoul (KR)

(72) Inventors: Jaekoo Park, Suwon-si (KR); Woo-Young Choi, Seoul-si (KR)

(73) Assignees: Samsung Electronics Co., Ltd., Suwon-si (KR); Uif (University Industry Foundation), Yonsei University, Seoul (KR)

(21) Appl. No.: 19/577,320

(22) Filed: Mar. 24, 2026

(30) Foreign Application Priority Data
Apr. 17, 2025 (KR) 10-2025-0050423

(51) Int. Cl. G01R 31/317; G11C 7/22; H03K 5/156

(52) U.S. Cl. CPC G01R 31/31727; G11C 7/222; H03K 5/1565; G11C 2207/2254

(57) ABSTRACT

A semiconductor device includes at least one transmission circuit configured to receive clock signals and transmit a data output signal, and a clock calibration circuit configured to convert the data output signal into a data code corresponding to an average level of the data output signal and generate a control signal. The at least one transmission circuit includes a clock correcting circuit configured to adjust a duty cycle or a phase difference of each of the clock signals in response to the control signal and generate corrected clock signals, and a pattern generating circuit configured to generate data of a pre-designated test pattern for a calibration operation of the clock calibration circuit.

### CROSS-REFERENCE TO RELATED APPLICATION(S)

This application is based on and claims priority under 35 U.S.C. § 119 to Korean Patent Application No. 10-2025-0050423, filed on Apr. 17, 2025, in the Korean Intellectual Property Office, the disclosure of which is incorporated by reference herein in its entirety.

### BACKGROUND

The inventive concept relates to a semiconductor device and an operating method thereof, and more particularly, to a semiconductor device including a transmission circuit for transmitting a data output signal according to a clock signal, and an operating method of the semiconductor device.

Due to recent advancements in data technology, communication circuits are required to smoothly transmit and receive large amounts of data. In this regard, a method of transmitting data may be divided into serial transmission and parallel transmission. Serial transmission refers to a method of transmitting data sequentially, one bit at a time, by using a single transmission line, and parallel transmission refers to a method of transmitting multiple bits of data simultaneously by using multiple transmission lines. Serial transmission has advantages in terms of cost and design due to the decrease in the number of transmission lines, but has the disadvantage of slow data transmission speed due to the sequential transmission of data by using a single transmission line. In contrast, parallel transmission has the advantage of fast data transmission speed due to the simultaneous transmission of multiple bits of data by using multiple transmission lines, but has disadvantages in terms of cost and design due to the increase in the number of transmission lines.

A plurality of clock signals may be used for serial transmission of data, and it may be necessary to detect and correct duty cycle errors of the plurality of clock signals or phase errors of the plurality of clock signals.

### SUMMARY

The inventive concept provides a semiconductor device capable of efficiently detecting and correcting duty cycle errors or phase errors of a plurality of clock signals, and an operating method of the semiconductor device.

According to an aspect of the inventive concept, there is provided a semiconductor device including at least one transmission circuit configured to receive clock signals and transmit a data output signal, and a clock calibration circuit configured to convert the data output signal into a data code corresponding to an average level of the data output signal and generate a control signal. The at least one transmission circuit includes a clock correcting circuit configured to adjust a duty cycle or a phase difference of each of the clock signals in response to the control signal and generate corrected clock signals, and a pattern generating circuit configured to generate data of a pre-designated test pattern for a calibration operation of the clock calibration circuit.

According to another aspect of the inventive concept, there is provided an operating method of a semiconductor device, the operating method including generating a first data code and a second data code according to respective average levels of a data output signal of a first data pattern corresponding to a first clock signal and a data output signal of a second data pattern corresponding to the first clock signal, generating a first reference data code by performing an operation on the first data code and the second data code, and adjusting a duty cycle of the first clock signal according to a result of comparing the first reference data code with the second data code.

According to another aspect of the inventive concept, there is provided an operating method of a semiconductor device that generates a data output signal according to first to fourth clock signals having different phases from one another, the operating method including generating a first data code and a second data code according to respective average levels of a data output signal of a first data pattern corresponding to the first clock signal and a data output signal of a second data pattern corresponding to the first clock signal, generating a third data code and a fourth data code according to respective average levels of a data output signal of a first data pattern corresponding to the second clock signal and a data output signal of a second data pattern corresponding to the second clock signal, generating a fifth data code and a sixth data code according to respective average levels of a data output signal of a first data pattern corresponding to the third clock signal and a data output signal of a second data pattern corresponding to the third clock signal, generating a seventh data code and an eighth data code according to respective average levels of a data output signal of a first data pattern corresponding to the fourth clock signal and a data output signal of a second data pattern corresponding to the fourth clock signal, generating a first internal data code by performing an operation on the first data code and the second data code, generating a second internal data code by performing an operation on the third data code and the fourth data code, generating a third internal data code by performing an operation on the fifth data code and the sixth data code, generating a fourth internal data code by performing an operation on the seventh data code and the eighth data code, generating a reference data code by performing an operation on the first to fourth internal data codes, adjusting the phase of the first clock signal according to a result of comparing the reference data code with the first internal data code, adjusting the phase of the second clock signal according to a result of comparing the reference data code with the second internal data code, adjusting the phase of the third clock signal according to a result of comparing the reference data code with the third internal data code, and adjusting the phase of the fourth clock signal according to a result of comparing the reference data code with the fourth internal data code.

### BRIEF DESCRIPTION OF THE DRAWINGS

Embodiments will be more clearly understood from the following detailed description taken in conjunction with the accompanying drawings in which:

FIG. 1 is a block diagram illustrating an electronic device according to the inventive concept;

FIG. 2A illustrates a plurality of clock signals provided to a transmission circuit, and FIG. 2B illustrates a data output signal output from a transmission circuit;

FIG. 3 is a block diagram illustrating a transmission circuit and a clock calibration circuit, which are included in a semiconductor device, according to the inventive concept;

FIG. 4 is a diagram illustrating an embodiment of a circuit configuration of a clock correcting circuit included in a transmission circuit, according to the inventive concept;

FIG. 5 is a diagram illustrating a 4:1 multiplexer (MUX) included in a serializer of a transmission circuit, according to the inventive concept;

FIG. 6 is a block diagram illustrating a plurality of transmission circuits and a clock calibration circuit, which are included in a semiconductor device, according to the inventive concept;

FIG. 7 is a flowchart illustrating an operating method of a semiconductor device according to the inventive concept;

FIGS. 8A and 8B are diagrams illustrating a test pattern for adjusting a duty cycle of a clock signal according to the inventive concept;

FIG. 9 is a diagram illustrating a computational operation performed to adjust a duty cycle of a clock signal according to the inventive concept;

FIGS. 10 and 11 are flowcharts illustrating an operating method of a semiconductor device according to the inventive concept;

FIG. 12 is a flowchart illustrating an operating method of a semiconductor device according to the inventive concept;

FIGS. 13A and 13B are diagrams illustrating a test pattern for adjusting a phase of a clock signal according to the inventive concept;

FIG. 14 is a diagram illustrating a computational operation performed to adjust a phase of a clock signal according to the inventive concept;

FIG. 15 is a flowchart illustrating an operating method of a semiconductor device according to the inventive concept; and

FIG. 16 is a block diagram illustrating a memory system according to the inventive concept.

### DETAILED DESCRIPTION OF THE EMBODIMENTS

Hereinafter, one or more embodiments of the inventive concept will be described in detail with reference to the attached drawings.

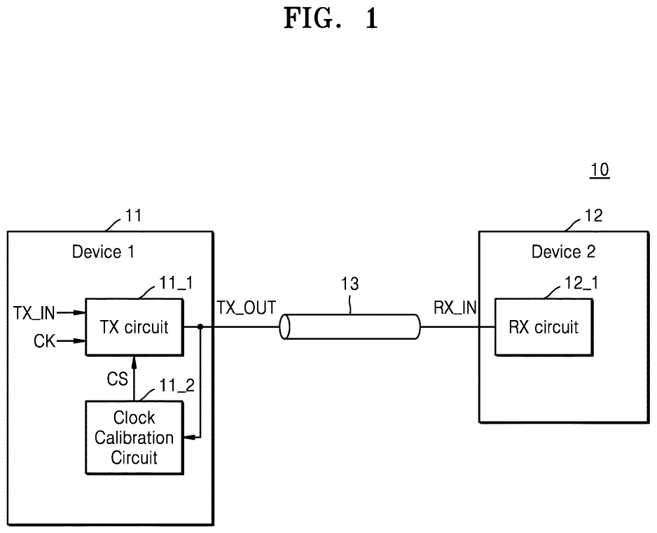

FIG. 1 is a block diagram illustrating an electronic device 10 according to the inventive concept.

Referring to FIG. 1, the electronic device 10 may include a first device 11 and a second device 12. In an embodiment, each of the first device 11 and the second device 12 may be referred to as a semiconductor device. For example, each of the first device 11 and the second device 12 may be one of various hardware components, for example, a processor, a memory device, a storage device, or a control device, included in a single user device.

The first device 11 and the second device 12 may exchange signals with each other through a communication channel 13. For example, the first device 11 may include a transmission (TX) circuit 11_1. The TX circuit 11_1 may transmit a data output signal TX_OUT to the second device 12 through the communication channel 13.

The TX circuit 11_1 may generate the data output signal TX_OUT, based on a clock signal CK and a data input signal TX_IN including a plurality of binary input bits. The data output signal TX_OUT may have a voltage level between a maximum voltage level and a minimum voltage level. For example, the maximum voltage level of the data output signal TX_OUT may be referred to as a high level, and the minimum voltage level of the data output signal TX_OUT may be referred to as a low level.

The first device 11 may include a clock calibration circuit 11_2. The clock calibration circuit 11_2 may be a circuit for detecting an error in a duty cycle or phase of the clock signal CK and correcting the error. The clock calibration circuit 11_2 may generate, by using the data output signal TX_OUT, a control signal CS for adjusting the duty cycle or phase of the clock signal CK. The clock calibration circuit 11_2 may transmit the control signal CS to the TX circuit 11_1, and the TX circuit 11_1 may generate a corrected clock signal in which the duty cycle or phase of the clock signal CK is adjusted in response to the control signal CS. The TX circuit 11_1 may generate the data output signal TX_OUT according to the corrected clock signal. For example, the clock signal CK may include first to fourth clock signals having different phases from one another, and the corrected clock signal may include first to fourth corrected clock signals having different phases from one another.

The clock calibration circuit 11_2 may receive the data output signal TX_OUT from an output terminal of the TX circuit 11_1 and generate the control signal CS for correcting the clock signal CK, and thus may perform a calibration operation for errors of the clock signal CK that may occur in all clock paths.

Also, the clock calibration circuit 11_2 may provide the TX circuit 11_1 with information on a pre-designated test pattern so that the data output signal TX_OUT of the pre-designated test pattern is generated to perform a calibration operation. The clock calibration circuit 11_2 may perform a calibration operation by using the data output signal TX_OUT generated according to each of a first data pattern and a second data pattern, which are pre-designated and different from each other, and thus, the calibration operation may also be applied to a single-ended data transmission scheme. That is, the first device 11 may be a semiconductor device that uses a single-ended data transmission scheme.

The second device 12 may include a reception (RX) circuit 12_1, and may receive a data input signal RX_IN through the communication channel 13. The second device 12 may further include a TX circuit, and may transmit a data signal to the first device 11.

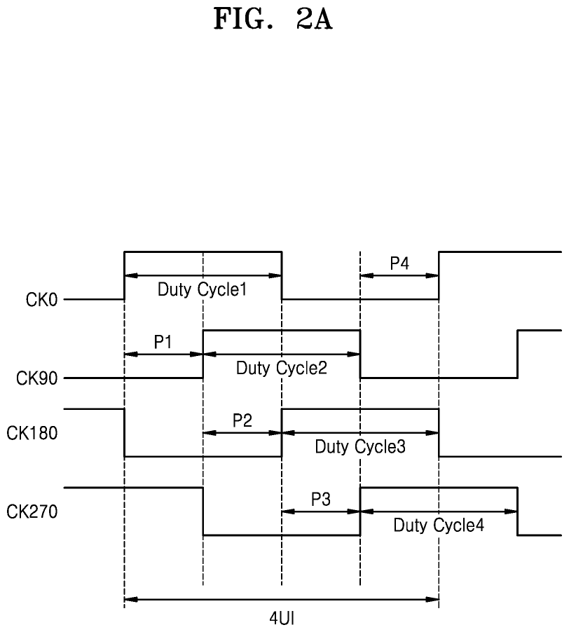

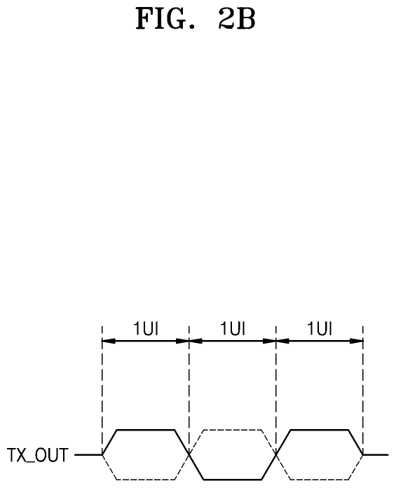

FIG. 2A illustrates a plurality of clock signals provided to a TX circuit, and FIG. 2B illustrates a data output signal output from a TX circuit.

Referring to FIGS. 2A and 2B, a time interval representing a single value in the data output signal TX_OUT may be defined as one unit interval (UI) (1UI). In this case, a period of first to fourth clock signals CK0, CK90, CK180, and CK270 may correspond to four UIs (4UI).

The first clock signal CK0 may have a first duty cycle (high-level period), and may have a phase delayed by a fourth phase difference P4 from the fourth clock signal CK270. The second clock signal CK90 may have a second duty cycle, and may have a phase delayed by a first phase difference P1 from the first clock signal CK0. The third clock signal CK180 may have a third duty cycle, and may have a phase delayed by a second phase difference P2 from the second clock signal CK90. The fourth clock signal CK270 may have a fourth duty cycle, and may have a phase delayed by a third phase difference P3 from the third clock signal CK180.

A clock calibration circuit (e.g., 11_2 in FIG. 1) may generate a control signal (e.g., CS in FIG. 1) for correcting the first to fourth clock signals CK0, CK90, CK180, and CK270 such that the first to fourth duty cycles all have the same value (i.e., two UIs), and the first to fourth phase differences P1 to P4 all have the same value (i.e., 90 degrees).

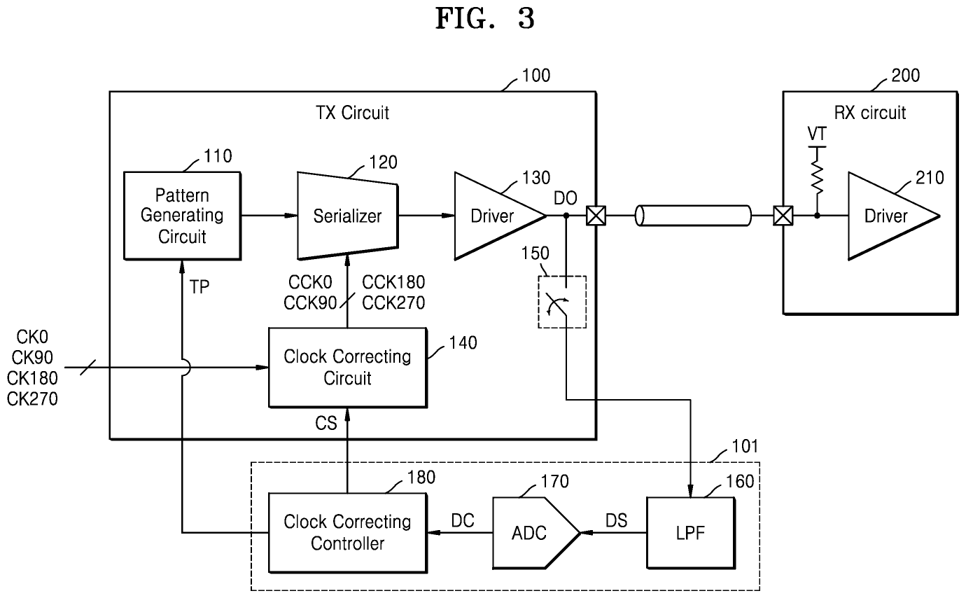

FIG. 3 is a block diagram illustrating a TX circuit 100 and a clock calibration circuit 101, which are included in a semiconductor device, according to the inventive concept.

Referring to FIG. 3, the TX circuit 100 may include a pattern generating circuit 110, a serializer 120, a driver or a transmission driver 130, and a clock correcting circuit 140. Also, the TX circuit 100 may further include a switching circuit 150.

The pattern generating circuit 110 may provide data to the serializer 120. The pattern generating circuit 110 may generate data of a certain pattern. For example, the pattern generating circuit 110 may generate data of a pre-designated test pattern for a calibration operation (i.e., a clock signal error correction operation) of the clock calibration circuit 101. The clock calibration circuit 101 may transmit a signal TP for a pre-designated test pattern to the pattern generating circuit 110 to generate data of the pre-designated test pattern, and the pattern generating circuit 110 may generate the data of the pre-designated test pattern in response to the signal TP for the pre-designated test pattern. The pattern generating circuit 110 may be implemented with a register.

The serializer 120 may serialize data provided from the pattern generating circuit 110, based on a plurality of corrected clock signals, for example, first to fourth corrected clock signals CCK0, CCK90, CCK180, and CCK270. The serializer 120 may provide the serialized data to the driver 130.

The driver 130 may generate a data output signal DO based on the serialized data. The driver 130 may transmit the data output signal DO through a link or channel. The data output signal DO may correspond to the data output signal TX_OUT.

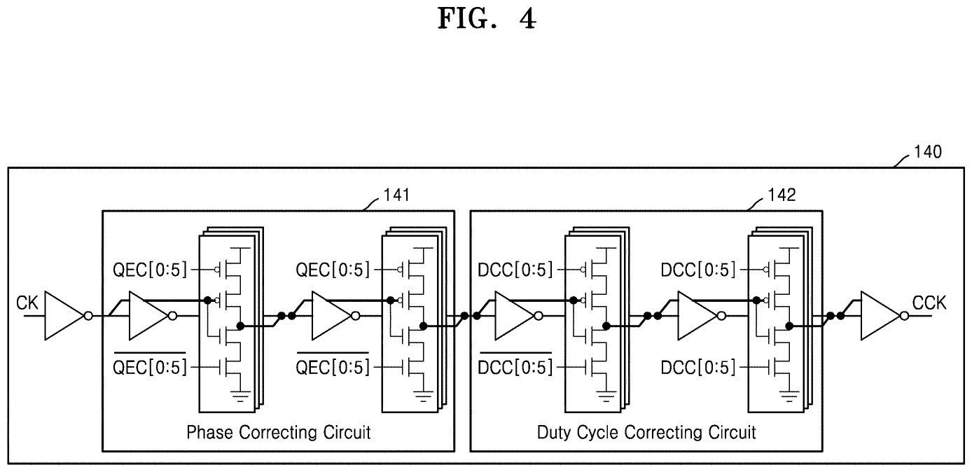

The clock correcting circuit 140 may receive a plurality of clock signals, for example, first to fourth clock signals CK0, CK90, CK180, and CK270, and may adjust a duty cycle or phase of each of the first to fourth clock signals CK0, CK90, CK180, and CK270 to generate the first to fourth corrected clock signals CCK0, CCK90, CCK180, and CCK270. For example, the clock correcting circuit 140 may generate the first to fourth corrected clock signals CCK0, CCK90, CCK180, and CCK270 to have the same duty cycle and a phase difference of 90 degrees from one another. An example of an internal configuration of the clock correcting circuit 140 will be described below with reference to FIG. 4.

The switching circuit 150 may switch between an output pin of the TX circuit 100 and the clock calibration circuit 101. For example, when it is determined that a calibration operation for the first to fourth clock signals CK0, CK90, CK180, and CK270 is required, the switching circuit 150 may be turned on, and the clock calibration circuit 101 may operate. In contrast, when a calibration operation for the first to fourth clock signals CK0, CK90, CK180, and CK270 is not required, the switching circuit 150 may be turned off so as not to affect the transmission of the data output signal DO. In an embodiment, the switching circuit 150 may be controlled by the clock calibration circuit 101, for example, by a clock correcting controller 180.

The clock calibration circuit 101 may receive the data output signal DO, and may generate a data code DC corresponding to an average level of the data output signal DO (or to a value corresponding to a period during which the data output signal DO has a high level within a designated cycle). The clock calibration circuit 101 may generate a control signal CS for adjusting a duty cycle or phase difference of each of the first to fourth clock signals CK0, CK90, CK180, and CK270 according to the data code DC.

For example, the clock calibration circuit 101 may generate a first data code and a second data code according to respective average levels of the data output signal DO of a first data pattern corresponding to the first clock signal CK0 and the data output signal DO of a second data pattern corresponding to the first clock signal CK0, may generate a reference data code by performing an operation on the first data code and the second data code, and may generate the control signal CS for adjusting the duty cycle of the first clock signal CK0, according to a result of comparing the reference data code with the second data code. By performing the same operation for the second clock signal CK90, the third clock signal CK180, and the fourth clock signal CK270, the clock calibration circuit 101 may generate the control signal CS for adjusting the duty cycle of each of the second clock signal CK90, the third clock signal CK180, and the fourth clock signal CK270.

Also, for example, the clock calibration circuit 101 may generate a first data code and a second data code according to respective average levels of the data output signal DO of a first data pattern corresponding to the first clock signal CK0 and the data output signal DO of a second data pattern corresponding to the first clock signal CK0, may generate a third data code and a fourth data code according to respective average levels of the data output signal DO of a first data pattern corresponding to the second clock signal CK90 and the data output signal DO of a second data pattern corresponding to the second clock signal CK90, may generate a fifth data code and a sixth data code according to respective average levels of the data output signal DO of a first data pattern corresponding to the third clock signal CK180 and the data output signal DO of a second data pattern corresponding to the third clock signal CK180, and may generate a seventh data code and an eighth data code according to respective average levels of the data output signal DO of a first data pattern corresponding to the fourth clock signal CK270 and the data output signal DO of a second data pattern corresponding to the fourth clock signal CK270. The clock calibration circuit 101 may generate a first internal data code by performing an operation on the first data code and the second data code, may generate a second internal data code by performing an operation on the third data code and the fourth data code, may generate a third internal data code by performing an operation on the fifth data code and the sixth data code, and may generate a fourth internal data code by performing an operation on the seventh data code and the eighth data code. The clock calibration circuit 101 may generate a reference data code by performing an averaging operation on the first to fourth internal data codes, may adjust a phase difference between the first clock signal CK0 and the second clock signal CK90 according to a result of comparing the reference data code with the first internal data code, may adjust a phase difference between the second clock signal CK90 and the third clock signal CK180 according to a result of comparing the reference data code with the second internal data code, may adjust a phase difference between the third clock signal CK180 and the fourth clock signal CK270 according to a result of comparing the reference data code with the third internal data code, and may adjust a phase difference between the fourth clock signal CK270 and the first clock signal CK0 according to a result of comparing the reference data code with the fourth internal data code. The clock calibration circuit 101 may generate the control signal CS for adjusting the phase differences each of the first to fourth clock signal CK0, CK90, CK180, and CK270.

In an embodiment, the clock calibration circuit 101 may include a low-pass filter (LPF) 160, an analog-to-digital conversion (ADC) circuit 170, and the clock correcting controller 180. The LPF 160 may generate a data signal DS by filtering the data output signal DO. The LPF 160 may generate the data signal DS corresponding to an average level of the data output signal DO (or to a value corresponding to a period during which the data output signal DO has a high level within a designated cycle). For example, the LPF 160 may integrate the data output signal DO over time, and may generate the data signal DS corresponding to the average of the integrated values over a certain period of time. In an embodiment, the LPF 160 may be a resistor-capacitor (RC) circuit including a resistor and a capacitor.

The ADC circuit 170 may analog-to-digital convert the data signal DS into the data code DC. The clock correcting controller 180 may generate the control signal CS based on the data code DC. For example, the clock correcting controller 180 may include a finite-state machine (FSM) for performing an operation on the data code DC. The clock correcting controller 180 may perform a subtraction operation, etc. on a pair of different data codes DC generated according to respective different data patterns, and may generate the control signal CS according to a result of performing a comparison operation on the pair of different data codes DC.

Also, the clock correcting controller 180 may transmit a signal TP for a pre-designated test pattern to the pattern generating circuit 110 to generate data of the pre-designated test pattern for a calibration operation. The clock correcting controller 180 may include a register set for generating the signal TP for the pre-designated test pattern. The pattern generating circuit 110 may generate the data of the pre-designated test pattern based on the signal TP.

The clock calibration circuit 101 may receive the data output signal DO from an output terminal of the TX circuit 100 and generate the control signal CS for correcting the first to fourth clock signals CK0, CK90, CK180, and CK270, and thus may perform a calibration operation for errors of the first to fourth clock signals CK0, CK90, CK180, and CK270 that may occur in all clock paths.

In an embodiment, the clock calibration circuit 101 may include a comparator and a counter, instead of the LPF 160 and the ADC circuit 170. For example, the comparator may compare the data output signal DO with a reference voltage, and the counter may generate the data code DC by counting a comparison result of the comparator. By the comparator and the counter, information on the length of a period during which the data output signal DO is equal to or higher than a specific level (reference voltage) may be converted into a value counted by the counter, and may be generated as the data code DC.

The clock calibration circuit 101 according to the inventive concept may be implemented to include the LPF 160 and the ADC circuit 170 or to include a comparator and a counter, and thus may be implemented with a simple circuit configuration.

An RX circuit 200 may receive a data input signal through a channel or link. The RX circuit 200 may include a driver 210, and the driver 210 may receive the data input signal and generate an internal data signal.

FIG. 4 is a diagram illustrating an embodiment of a circuit configuration of the clock correcting circuit 140 included in the TX circuit 100, according to the inventive concept. The clock correcting circuit 140 may be referred to as a digitally controlled delay line (DCDL) circuit. The circuit configuration of the clock correcting circuit 140 illustrated in FIG. 4 is only an example, and may be variously modified.

Referring to FIG. 4, the clock correcting circuit 140 may include a phase correcting circuit 141 and a duty cycle correcting circuit 142. The clock correcting circuit 140 may further include a plurality of inverters. The clock correcting circuit 140 may generate a corrected clock signal CCK by adjusting a phase or duty cycle of a clock signal CK according to a control signal (e.g., CS in FIG. 2A) including a first control code QEC[0:5] and a second control code DCC[0:5]. The clock signal CK may be one of the first to fourth clock signals CK0, CK90, CK180, and CK270 of FIG. 3, and the corrected clock signal CCK may be one of the first to fourth corrected clock signals CCK0, CCK90, CCK180, and CCK270 of FIG. 3.

The phase correcting circuit 141 may include a plurality of inverters, and may include a plurality of P-type transistors of which operation is controlled according to the first control code QEC[0:5], and a plurality of N-type transistors of which operation is controlled according to an inverted code of the first control code QEC[0:5]. The number of bits of the first control code QEC[0:5] may vary depending on the number of P-type transistors and the number of N-type transistors. Due to the characteristics of the P-type transistors and the N-type transistors, as a code value of the first control code QEC[0:5] increases, the phase of the clock signal CK may be increased (delayed), and the corrected clock signal CCK may be generated.

The duty cycle correcting circuit 142 may include a plurality of inverters, and may include a plurality of P-type transistors and a plurality of N-type transistors, which are controlled according to the second control code DCC[0:5] or an inverted code of the second control code DCC[0:5]. The number of bits of the second control code DCC[0:5] may vary depending on the number of P-type transistors and the number of N-type transistors. Due to the characteristics of the P-type transistors and the N-type transistors, as a code value of the second control code DCC[0:5] increases, the duty cycle of the clock signal CK may be increased, and the corrected clock signal CCK may be generated.

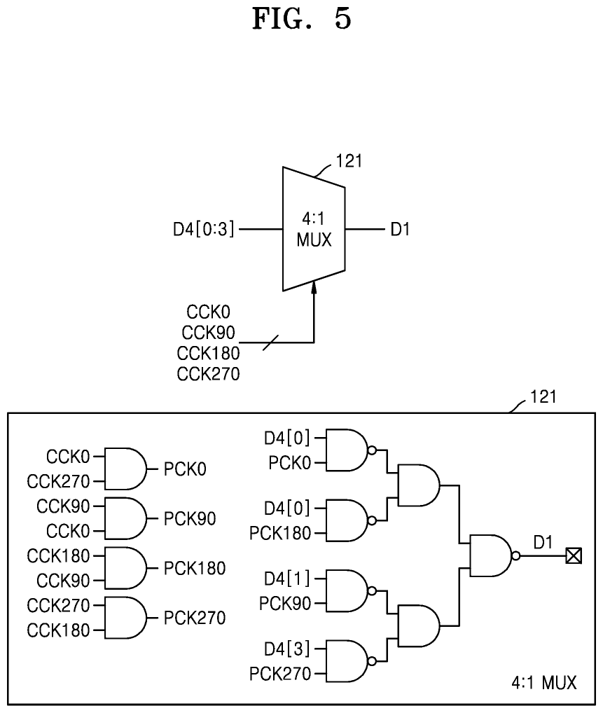

FIG. 5 is a diagram illustrating a 4:1 multiplexer (MUX) 121 included in the serializer 120 of the TX circuit 100, according to the inventive concept.

Referring to FIG. 5, the 4:1 MUX 121 included in the serializer 120 may receive parallel data D4[0:3] and a plurality of corrected clock signals (e.g., first to fourth corrected clock signals CCK0, CCK90, CCK180, and CCK270). For example, the parallel data D4[0:3] may include first data D4[0], second data D4[1], third data D4[2], and fourth data D4[3] that are sequentially input. The first to fourth corrected clock signals CCK0, CCK90, CCK180, and CCK270 may ideally have a phase difference of 90 degrees from one another.

In an embodiment, the 4:1 MUX 121 may include a plurality of AND gates and a plurality of NAND gates. The 4:1 MUX 121 may generate a first internal clock signal PCK0 by performing an AND operation on the first corrected clock signal CCK0 and the fourth corrected clock signal CCK270, may generate a second internal clock signal PCK90 by performing an AND operation on the second corrected clock signal CCK90 and the first corrected clock signal CCK0, may generate a third internal clock signal PCK180 by performing an AND operation on the third corrected clock signal CCK180 and the second corrected clock signal CCK90, and may generate a fourth internal clock signal PCK270 by performing an AND operation on the fourth corrected clock signal CCK270 and the third corrected clock signal CCK180.

The 4:1 MUX 121 may generate first intermediate data by performing an AND operation on first result data, which is obtained by performing a NAND operation on the first data D4[0] and the first internal clock signal PCK0, and second result data, which is obtained by performing a NAND operation on the third data D4[2] and the third internal clock signal PCK180. The 4:1 MUX 121 may generate second intermediate data by performing an AND operation on third result data, which is obtained by performing a NAND operation on the second data D4[1] and the second internal clock signal PCK90, and fourth result data, which is obtained by performing a NAND operation on the fourth data D 4[3] and the fourth internal clock signal PCK270. The 4:1 MUX 121 may output serial data D1 by performing a NAND operation on the first intermediate data and the second intermediate data.

A transition from 0 to 1 of the serial data D1 may occur at the rising edge of each of the first to fourth corrected clock signals CCK0, CCK90, CCK180, and CCK270, and a transition from 1 to 0 of the serial data D1 may occur at the falling edge of each of the first to fourth corrected clock signals CCK0, CCK90, CCK180, and CCK270.

For example, when a value of the fourth data D4[3] in the serial data D1 transitions to a value of the first data D4[0], in the case of a transition from 0 to 1, the rising edge of the first corrected clock signal CCK0 may be involved, and in the case of a transition from 1 to 0, the falling edge of the third corrected clock signal CCK180 may be involved. When a value of the first data D4[0] in the serial data D1 transitions to a value of the second data D4[1], in the case of a transition from 0 to 1, the rising edge of the second corrected clock signal CCK90 may be involved, and in the case of a transition from 1 to 0, the falling edge of the fourth corrected clock signal CCK270 may be involved. When a value of the second data D4[1] in the serial data D1 transitions to a value of the third data D4[2], in the case of a transition from 0 to 1, the rising edge of the third corrected clock signal CCK180 may be involved, and in the case of a transition from 1 to 0, the falling edge of the first corrected clock signal CCK0 may be involved. Also, when a value of the third data D4[2] in the serial data D1 transitions to a value of the fourth data D4[3], in the case of a transition from 0 to 1, the rising edge of the fourth corrected clock signal CCK270 may be involved, and in the case of a transition from 1 to 0, the falling edge of the second corrected clock signal CCK90 may be involved.

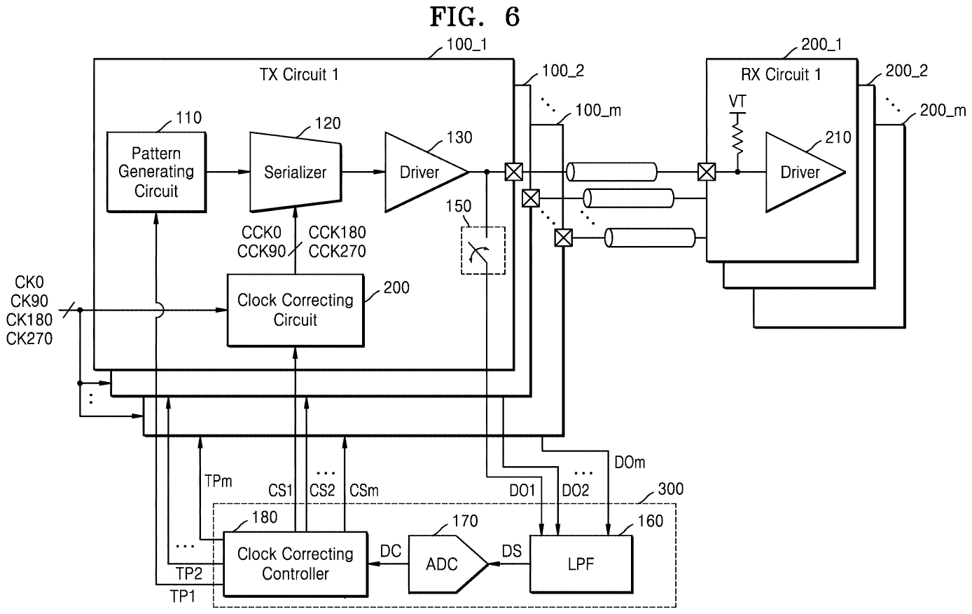

FIG. 6 is a block diagram illustrating a plurality of TX circuits and a clock calibration circuit 300, which are included in a semiconductor device, according to the inventive concept.

Referring to FIG. 6, each of the plurality of TX circuits, for example, first to mth TX circuits 100_1 to 100_m, may communicate with a corresponding RX circuit (e.g., a corresponding one of 200_1 to 200_m) through a corresponding channel. Each of the first to mth TX circuits 100_1 to 100_m may include the pattern generating circuit 110, the serializer 120, the driver 130, the clock correcting circuit 140, and the switching circuit 150. The pattern generating circuit 110, the serializer 120, the driver 130, the clock correcting circuit 140, and the switching circuit 150 included in each of the first to mth TX circuits 100_1 to 100_m may be respectively the same as the pattern generating circuit 110, the serializer 120, the driver 130, the clock correcting circuit 140, and the switching circuit 150 described with reference to FIG. 3.

The clock calibration circuit 300 may perform calibration operations for generating first to fourth corrected clock signals CCK0, CCK90, CCK180, and CCK270, which are used in each of the first to mth TX circuits 100_1 to 100_m, by adjusting duty cycles or phases of first to fourth clock signals CK0, CK90, CK180, and CK270. For example, the clock calibration circuit 300 may perform calibration operations for each of the first to mth TX circuits 100_1 to 100_m.

The clock calibration circuit 300 may transmit a signal (a corresponding one of TP1 to TPm) for a pre-designated test pattern to the pattern generating circuit 110 included in each of the first to mth TX circuits 100_1 to 100_m, so as to generate data of the pre-designated test pattern for performing a calibration operation.

The clock calibration circuit 300 may receive, from each of the first to mth TX circuits 100_1 to 100_m, a data output signal generated according to a test pattern. For example, the clock calibration circuit 300 may receive a first data output signal DO1 as the data output signal TX_OUT from the first TX circuit 100_1, a second data output signal DO2 as the data output signal TX_OUT from the second TX circuit 100_2, and an mth data output signal DOm as the data output signal TX_OUT from the mth TX circuit 100_m.

As the switching circuits 150 respectively included in the first to mth TX circuits 100_1 to 100_m are turned on at different timings, the clock calibration circuit 300 may receive the first to mth data output signals DO1 to DOm at different timings, respectively.

The clock calibration circuit 300 may convert a value corresponding to an average level of each of the first to mth data output signals DO1 to DOm into a data code DC. The cclko calibration circuit 300 may generate first to mth control signals CS1 to CSm for the first to mth TX circuits 100_1 to 100_m according to the data code DC. For example, the clock calibration circuit 300 may transmit a first control signal CS1 as the control signal CS to the first TX circuit 100_1, a second control signal CS2 as the control signal CS to the second TX circuit 100_2, and an mth control signal CSm as the control signal CS to the mth TX circuit 100_m.

Also, the clock calibration circuit 300 according to the inventive concept may be implemented with a simple circuit configuration, and the clock calibration circuit 300 may be connected to a plurality of TX circuits to perform a calibration operation for each of the plurality of TX circuits, thereby reducing an increase in area due to the clock calibration circuit 300.

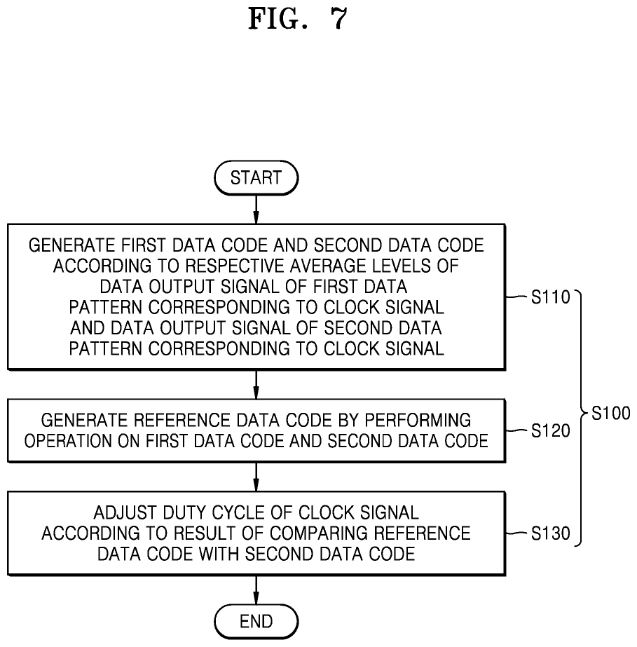

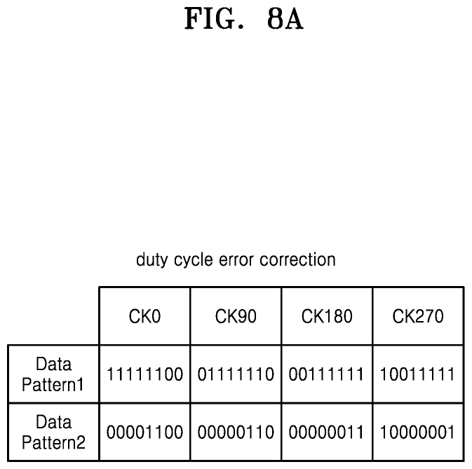

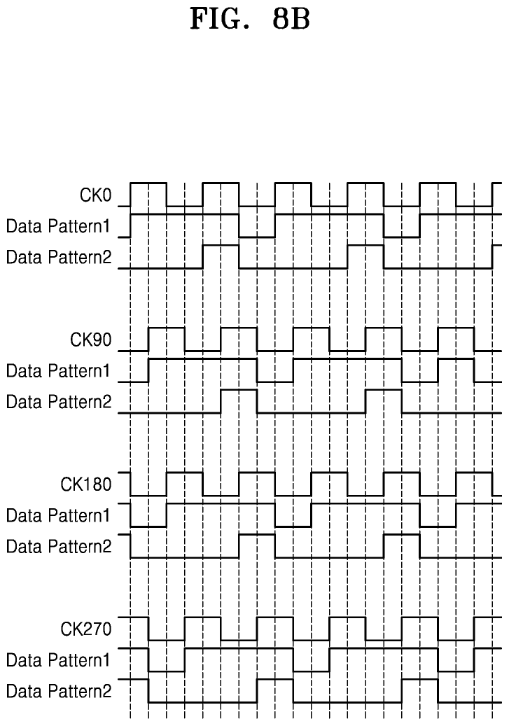

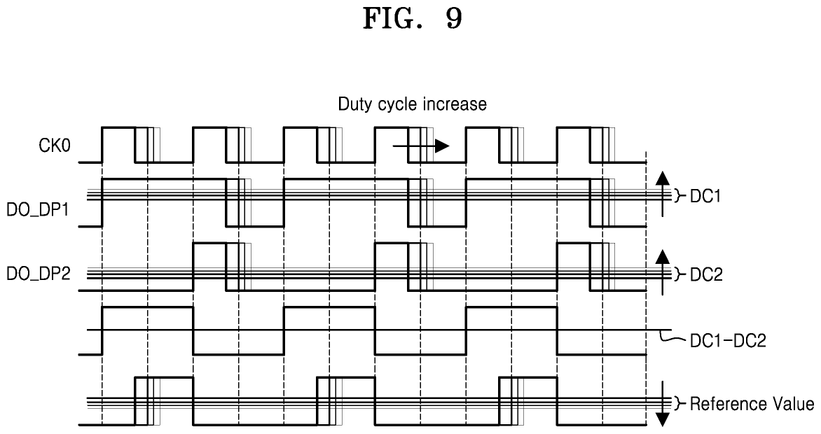

FIG. 7 is a flowchart illustrating an operating method of a semiconductor device according to the inventive concept. FIGS. 8A and 8B are diagrams illustrating a test pattern for adjusting a duty cycle of a clock signal according to the inventive concept. FIG. 9 is a diagram illustrating a computational operation performed to adjust a duty cycle of a clock signal according to the inventive concept. The operating method of the semiconductor device, described with respect to FIG. 7, may be performed by a clock calibration circuit as a method of adjusting a duty cycle of a clock signal.

Referring to FIG. 7, operation S100 may include operations S110 to S130. Hereinafter, one clock signal (a first clock signal) among first to fourth clock signals is described as an example, but operation S100 may be performed for each of the first to fourth clock signals.

In operation S110, a first data code and a second data code may be generated according to respective average levels of a data output signal of a first data pattern corresponding to a clock signal and a data output signal of a second data pattern corresponding to the clock signal. For example, the first data code may be generated by low-pass filtering and analog-to-digital converting the data output signal of the first data pattern, and the second data code may be generated by low-pass filtering and analog-to-digital converting the data output signal of the second data pattern. In an embodiment, a first data code that is linearly proportional to the amount of change in a duty cycle of the clock signal may be generated according to data of the first data pattern, and a second data code that is linearly proportional to the amount of change in the duty cycle of the clock signal may be generated according to data of the second data pattern. In this regard, the first data code and the second data code may have the same slopes that are linearly proportional to the amount of change in the duty cycle. In an embodiment, the pattern generating circuit 110 may generate the first data of the first data pattern and the second data of the second data pattern for the calibration operation. The clock calibration circuit (e.g., the clock calibration circuits 11_2, 101, 101a, and/or 300) may generate, according to the first data, the first data code that is linearly proportional to an amount of change in a duty cycle of a target clock signal. The clock calibration circuit (e.g., the clock calibration circuits 11_2, 101, 101a, and/or 300) may generate, according to the second data, the second data code that is linearly proportional to the amount of change in the duty cycle of the target clock signal. The clock correcting circuit 140 may adjust the duty cycle of the target clock signal among the first to fourth clock signals.

Referring to FIGS. 8A and 8B, the first data pattern and the second data pattern, which are test patterns for adjusting a duty cycle of a clock signal, are illustrated, and the first data pattern and the second data pattern corresponding to each of the first to fourth clock signals are illustrated. In an embodiment, data of the first data pattern corresponding to the second clock signal may have a pattern delayed by integer multiple the UI of the data output signal from data of the first data pattern corresponding to the first clock signal. Data of the second data pattern corresponding to the second clock signal may have a pattern delayed by integer multiple the UI of the data output signal from data of the second data pattern corresponding to the first clock signal. Data of the first data pattern corresponding to the third clock signal and data of the second data pattern corresponding to the third clock signal may have a pattern delayed by integer multiple the UI of the data output signal from data of the first data pattern corresponding to the second clock signal and data of the second data pattern corresponding to the second clock signal, respectively. Data of the first data pattern corresponding to the fourth clock signal and the data of the second data pattern corresponding to the fourth clock signal may have a pattern delayed by integer multiple the UI of the data output signal from data of the first data pattern corresponding to the third clock signal and data of the second data pattern corresponding to the third clock signal, respectively. For example, Data of the first data pattern corresponding to the second clock signal may have a pattern delayed by the UI (1UI) of the data output signal from data of the first data pattern corresponding to the first clock signal. Also, data of the second data pattern corresponding to the second clock signal may have a pattern delayed by the UI (1UI) of the data output signal from data of the second data pattern corresponding to the first clock signal. Data of the first data pattern corresponding to the third clock signal and data of the second data pattern corresponding to the third clock signal may have a pattern delayed by the UI (1UI) of the data output signal from data of the first data pattern corresponding to the second clock signal and data of the second data pattern corresponding to the second clock signal, respectively, and data of the first data pattern corresponding to the fourth clock signal and the data of the second data pattern corresponding to the fourth clock signal may have a pattern delayed by the UI (1UI) the UI of the data output signal from data of the first data pattern corresponding to the third clock signal and data of the second data pattern corresponding to the third clock signal, respectively. For example, data of the first data pattern corresponding to the second clock signal may have a pattern delayed by twice (2UI) the UI of the data output signal from data of the first data pattern corresponding to the first clock signal. Also, data of the second data pattern corresponding to the second clock signal may have a pattern delayed by twice (2UI) the UI of the data output signal from data of the second data pattern corresponding to the first clock signal. Data of the first data pattern corresponding to the third clock signal and data of the second data pattern corresponding to the third clock signal may have a pattern delayed by twice (2UI) the UI of the data output signal from data of the first data pattern corresponding to the second clock signal and data of the second data pattern corresponding to the second clock signal, respectively, and data of the first data pattern corresponding to the fourth clock signal and data of the second data pattern corresponding to the fourth clock signal may have a pattern delayed by twice (2UI) the UI of the data output signal from data of the first data pattern corresponding to the third clock signal and data of the second data pattern corresponding to the third clock signal, respectively.

In an embodiment, the first data pattern and the second data pattern corresponding to each of the first to fourth clock signals CK0, CK90, CK180, and CK270 may be configured such that an 8-bit pattern is repeated. For example, the first data pattern corresponding to the first clock signal CK0 may be ‘11111100,’ the second data pattern corresponding to the first clock signal CK0 may be ‘00001100,’ the first data pattern corresponding to the second clock signal CK90 may be ‘01111110,’ and the second data pattern corresponding to the second clock signal CK90 may be ‘00000110.’ Also, for example, the first data pattern corresponding to the third clock signal CK180 may be ‘00111111,’ the second data pattern corresponding to the third clock signal CK180 may be ‘00000011,’ the first data pattern corresponding to the fourth clock signal CK270 may be ‘10011111,’ and the second data pattern corresponding to the fourth clock signal CK270 may be ‘10000001.’

However, the inventive concept is not limited thereto, and in an embodiment, the first data pattern and the second data pattern corresponding to each of the first to fourth clock signals CK0, CK90, CK180, and CK270 may be configured such that a 24-bit pattern is repeated. For example, the first data pattern corresponding to the first clock signal CK0 may be ‘0xFFFFC0,’ and the second data pattern corresponding to the first clock signal CK0 may be ‘0x000FC0.’

Referring to FIGS. 7 and 9 together, in operation S120, a reference data code may be generated by performing an operation on the first data code and the second data code. The first data code and the second data code may have values that are linearly proportional to the amount of change in the duty cycle of the clock signal, and the reference data code may have a value that is linearly inversely proportional to the amount of change in the duty cycle of the clock signal. In an embodiment, the reference data code may be generated to have a value obtained by subtracting twice the value of the second data code from the value of the first data code.

For example, ΔDuty Cycle may be defined as the amount of change in the duty cycle from the ideal duty cycle (50% duty ratio) of the clock signal, VH may be defined as the maximum voltage level (high level) of the data output signal, and VL may be defined as the minimum voltage level (low level, assumed to be 0) of the data output signal.

When the first data pattern corresponding to the first clock signal CK0 is ‘11111100’ and the second data pattern corresponding to the first clock signal CK0 is ‘00001100,’ a code value DC1 of the first data code generated according to a data output signal DO_DP1 of the first data pattern may correspond to (VH)×(0.75+ΔDuty Cycle), and a code value DC2 of the second data code generated according to a data output signal DO_DP2 of the second data pattern may correspond to (VH)×(0.25+ΔDuty Cycle). By subtracting the code value DC2 of the second data code from the code value DC1 of the first data code, (VH)×0.5 may have a constant value regardless of ΔDuty Cycle.

The reference data code may have a reference value corresponding to VH×(0.25−ΔDuty Cycle), which is a value obtained by subtracting twice the code value DC2 of the second data code from the code value DC1 of the first data code. Accordingly, by comparing the reference data code with the second data code, it may be determined whether the amount of change in the duty cycle (ΔDuty Cycle) is a positive number, a negative number, or 0, and the duty cycle of the first clock signal CK0 may be adjusted such that the amount of change in the duty cycle (ΔDuty Cycle) becomes 0.

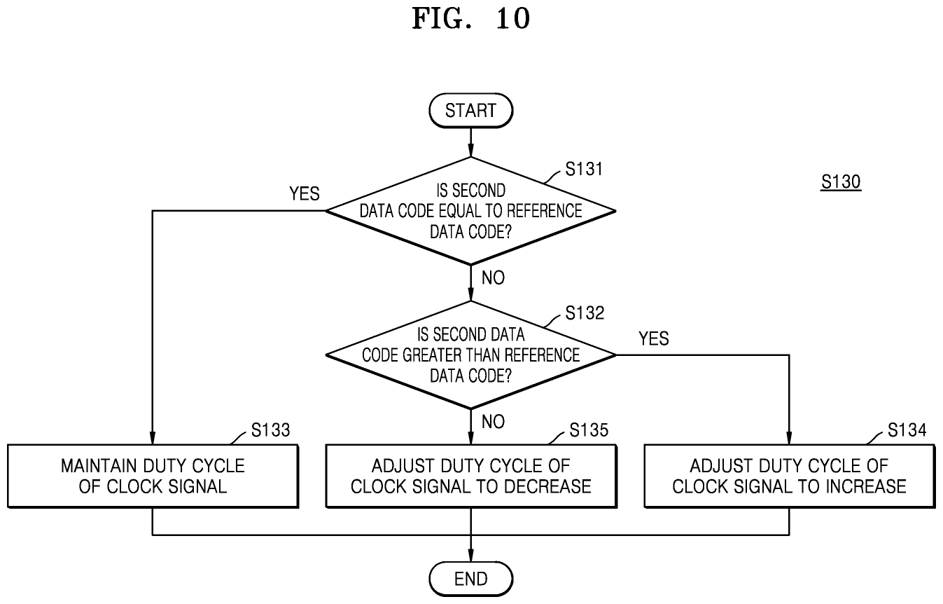

Referring to FIG. 7, in operation S130, the duty cycle of the clock signal may be adjusted according to a result of comparing the reference data code with the second data code. Operation S130 will be described in detail below with reference to FIG. 10.

FIG. 10 is a flowchart illustrating an operating method of a semiconductor device according to the inventive concept. Operation S130 may include operations S131 to S135.

Referring to FIG. 10, in operation S131, it may be determined whether the second data code is equal to the reference data code, and in operation S132, it may be determined whether the second data code is greater than the reference data code. In an embodiment, the first data code corresponding to the first data pattern may have a value that is linearly proportional to the amount of change in the duty cycle, and the second data code corresponding to the second data pattern may have a value that is linearly proportional to the amount of change in the duty cycle.

The reference data code may have a value that is linearly inversely proportional to the amount of change in the duty cycle. In an embodiment, the magnitude of a slope by which the first data code and the second data code are proportional to the amount of change in the duty cycle may be equal to the magnitude of a slope by which the reference data code is linearly inversely proportional to the amount of change in the duty cycle. By subtracting the second data code from the first data code, a constant value may be obtained regardless of the amount of change in the duty cycle, and in an embodiment, the reference data code may have a value obtained by subtracting the second data code again from the constant value.

In operation S133, when the second data code is equal to the reference data code, the duty cycle of the clock signal may be maintained. When the second data code is equal to the reference data code, the amount of change in the duty cycle is 0, and thus, the duty cycle may be maintained as is.

Because the second data code has a value that is linearly proportional to the amount of change in the duty cycle, and the reference data code has a value that is linearly inversely proportional to the amount of change in the duty cycle, in operation S134, when the second data code has a value greater than the reference data code, the duty cycle of the clock signal may be adjusted to decrease, and in operation S135, when the second data code has a value less than the reference data code, the duty cycle of the clock signal may be adjusted to increase.

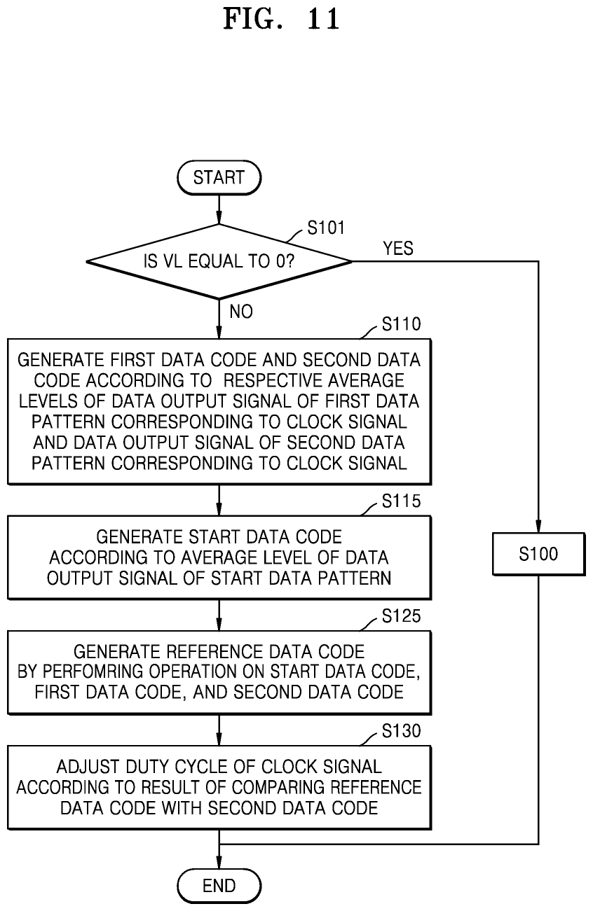

FIG. 11 is a flowchart illustrating an operating method of a semiconductor device according to the inventive concept. The operating method of the semiconductor device, described with respect to FIG. 11, may be performed by a clock calibration circuit as a method of adjusting a duty cycle of a clock signal.

Referring to FIG. 11, in operation S101, it may be determined whether a low level VL (minimum voltage level) of a data output signal is 0, and when the low level VL of the output data signal is 0, operation S100 described with reference to FIG. 7 may be performed.

When the low level VL of the data output signal is not 0, operation S110 described with reference to FIG. 7 and operation S115 may be performed. In operation S115, a start data code may be generated according to an average level of a data output signal of a start data pattern. For example, when a test pattern is an 8-bit data pattern, the start data pattern may be ‘00000000.’ Operation S115 may be an operation of obtaining a start data code corresponding to the low level VL of the data output signal.

In operation S125, a reference data code may be generated by performing an operation on the start data code, the first data code, and the second data code. In operation S130, the duty cycle of the clock signal may be adjusted according to a result of comparing the reference data code with the second data code.

For example, as described with reference to FIG. 8A, according to the data output signal of the first data pattern ‘11111100’ corresponding to the first clock signal CK0 and the data output signal of the second data pattern ‘00001100’ corresponding to the first clock signal CK0, the value of the first data code may be VL+(VH−VL)×(0.75+ΔDuty Cycle), and the value of the second data code may be VL+(VH−VL)×(0.25+ΔDuty Cycle). VH may be the maximum voltage level (high level) of the data output signal. By subtracting the value of the second data code from the value of the first data code, (VH−VL)×0.5 may have a constant value regardless of ΔDuty Cycle.

The reference data code may be VL+(VH-VL)×(0.25−ΔDuty Cycle), which is a value obtained by subtracting twice the value of the second data code from the value of the first data code and adding twice the value of the start data code to a result of the subtraction.

The reference data code may have a value that is linearly inversely proportional to the amount of change in the duty cycle of the clock signal. Accordingly, by comparing the reference data code with the second data code, it may be determined whether the amount of change in the duty cycle (ΔDuty Cycle) is a positive number, a negative number, or 0, and the duty cycle of the first clock signal CK0 may be adjusted such that the amount of change in the duty cycle (ΔDuty Cycle) becomes 0.

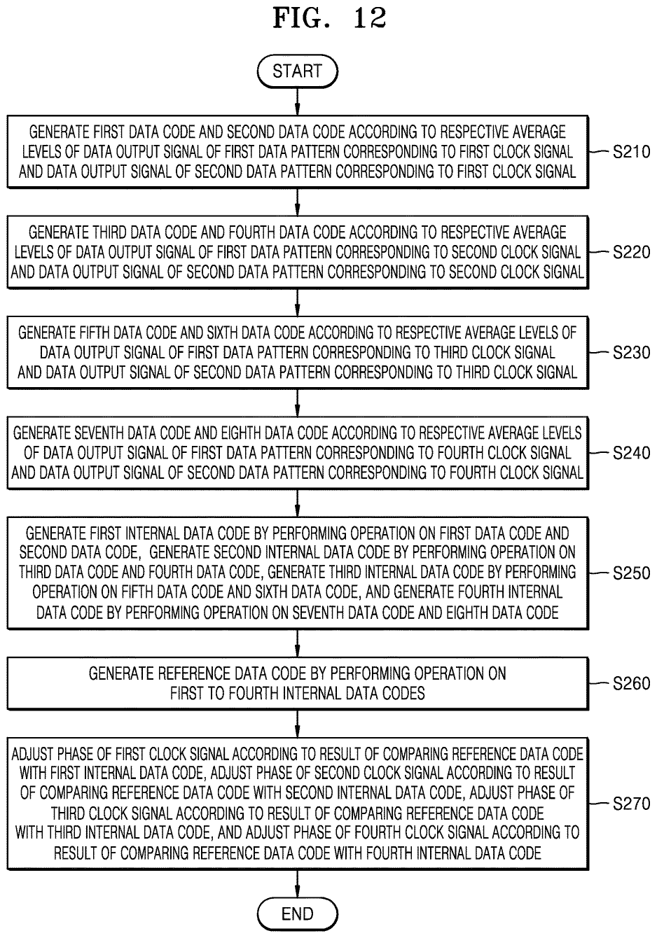

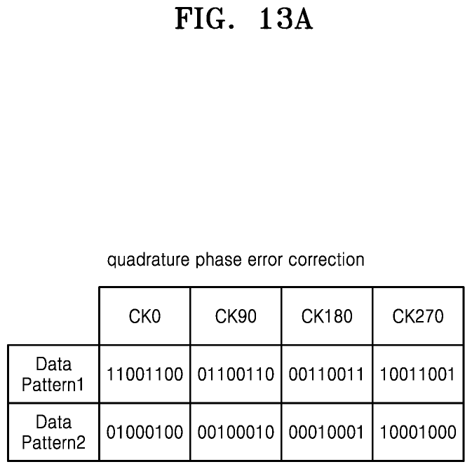

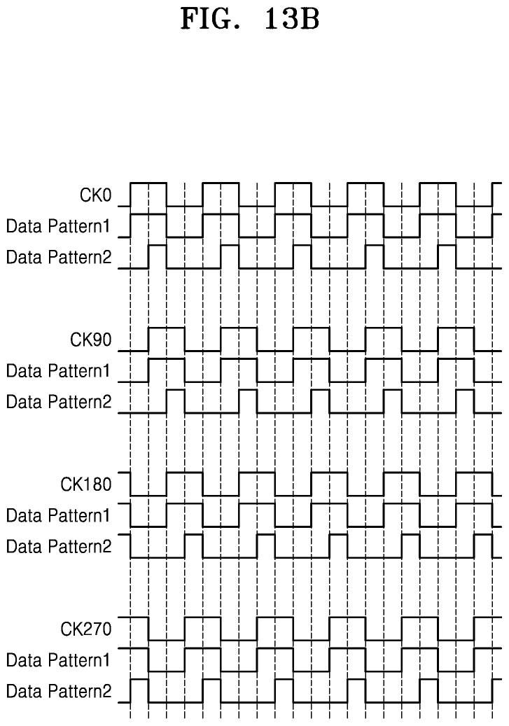

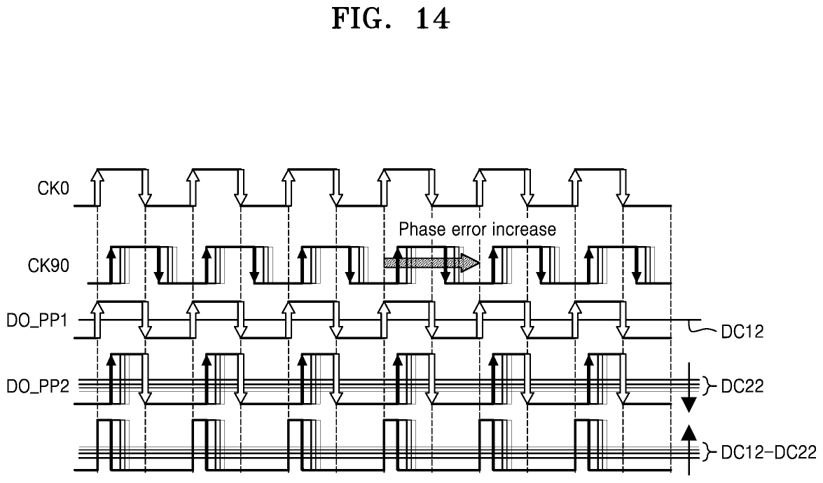

FIG. 12 is a flowchart illustrating an operating method of a semiconductor device according to the inventive concept. FIGS. 13A and 13B are diagrams illustrating a test pattern for adjusting a phase of a clock signal according to the inventive concept. FIG. 14 is a diagram illustrating a computational operation performed to adjust a phase of a clock signal according to the inventive concept. The operating method of the semiconductor device, described with respect to FIG. 12, may be performed by a clock calibration circuit as a method of adjusting a duty cycle of a clock signal.

Referring to FIG. 12, in operation S210, a first data code and a second data code may be generated according to respective average levels of a data output signal of a first data pattern corresponding to a first clock signal and a data output signal of a second data pattern corresponding to the first clock signal. In operation S220, a third data code and a fourth data code may be generated according to respective average levels of a data output signal of a first data pattern corresponding to a second clock signal and a data output signal of a second data pattern corresponding to the second clock signal. In operation S230, a fifth data code and a sixth data code may be generated according to respective average levels of a data output signal of a first data pattern corresponding to a third clock signal and a data output signal of a second data pattern corresponding to the third clock signal. In operation S240, a seventh data code and an eighth data code may be generated according to respective average levels of a data output signal of a first data pattern corresponding to a fourth clock signal and a data output signal of a second data pattern corresponding to the fourth clock signal.

For example, the first data code may be generated by low-pass filtering and analog-to-digital converting the data output signal of the first data pattern corresponding to the first clock signal, and the second data code may be generated by low-pass filtering and analog-to-digital converting the data output signal of the second data pattern corresponding to the first clock signal. The first data pattern and the second data pattern for controlling a phase of a specific clock signal may be patterns capable of generating a signal component that is proportional to a phase difference between the specific clock signal and a clock signal that is 90 degrees different from the specific clock signal. In an embodiment, the pattern generating circuit 110 may generate the first data of the first data pattern and the second data of the second data pattern for the calibration operation. The clock calibration circuit (e.g., the clock calibration circuits 11_2, 101, 101a, and/or 300) may generate the first data code according to the first data and the second data code according to the second data. The clock correcting circuit 140 may adjust a phase difference between the clock signals (e.g., the phase difference between the specific clock signal and a clock signal that is 90 degrees different from the specific clock signal). The difference value between the first data code and the second data code may be proportional to the phase difference between the clock signals.

Referring to FIGS. 13A and 13B, the first data pattern and the second data pattern, which are test patterns for adjusting a phase of a clock signal, are illustrated, and the first data pattern and the second data pattern corresponding to each of the first to fourth clock signals are illustrated. In an embodiment, data of the first data pattern corresponding to the second clock signal and data of the second data pattern corresponding to the second clock signal may have a pattern delayed by integer multiple the UI of the data output signal from the data of the first data pattern corresponding to the first clock signal and the data of the second data pattern corresponding to the first clock signal, respectively. Data of the first data pattern corresponding to the third clock signal and data of the second data pattern corresponding to the third clock signal may have a pattern delayed by integer multiple the UI of the data output signal from the data of the first data pattern corresponding to the second clock signal and the data of the second data pattern corresponding to the second clock signal, respectively. Data of the first data pattern corresponding to the fourth clock signal and data of the second data pattern corresponding to the fourth clock signal may have a pattern delayed by integer multiple the UI of the data output signal from the data of the first data pattern corresponding to the third clock signal and the data of the second data pattern corresponding to the third clock signal, respectively. For example, the data of the first data pattern corresponding to the second clock signal and the data of the second data pattern corresponding to the second clock signal may have a pattern delayed by the UI (1UI) of the data output signal from the data of the first data pattern corresponding to the first clock signal and the data of the second data pattern corresponding to the first clock signal. The data of the first data pattern corresponding to the third clock signal and the data of the second data pattern corresponding to the third clock signal may have a pattern delayed by the UI (1UI) of the data output signal from data of the first data pattern corresponding to the second clock signal and the data of the second data pattern corresponding to the second clock signal, respectively. The data of the first data pattern corresponding to the fourth clock signal and the data of the second data pattern corresponding to the fourth clock signal may have a pattern delayed by the UI (1UI) the UI of the data output signal from data of the first data pattern corresponding to the third clock signal and the data of the second data pattern corresponding to the third clock signal, respectively. For example, data of the first data pattern corresponding to the second clock signal may have a pattern delayed by twice (2UI) the UI of the data output signal from data of the first data pattern corresponding to the first clock signal. Also, data of the second data pattern corresponding to the second clock signal may have a pattern delayed by twice (2UI) the UI of the data output signal from data of the second data pattern corresponding to the first clock signal. Data of the first data pattern corresponding to the third clock signal and data of the second data pattern corresponding to the third clock signal may have a pattern delayed by twice (2UI) the UI of the data output signal from data of the first data pattern corresponding to the second clock signal and data of the second data pattern corresponding to the second clock signal, respectively, and data of the first data pattern corresponding to the fourth clock signal and the data of the second data pattern corresponding to the fourth clock signal may have a pattern delayed by twice (2UI) the UI of the data output signal from data of the first data pattern corresponding to the third clock signal and data of the second data pattern corresponding to the third clock signal, respectively.

In an embodiment, the first data pattern and the second data pattern corresponding to each of the first to fourth clock signals CK0, CK90, CK180, and CK270 may be configured such that an 8-bit pattern is repeated. For example, the first data pattern corresponding to the first clock signal CK0 may be ‘11001100,’ the second data pattern corresponding to the first clock signal CK0 may be ‘01000100,’ the first data pattern corresponding to the second clock signal CK90 may be ‘01100110,’ and the second data pattern corresponding to the second clock signal CK90 may be ‘00100010.’ Also, for example, the first data pattern corresponding to the third clock signal CK180 may be ‘00110011,’ the second data pattern corresponding to the third clock signal CK180 may be ‘00010001,’ the first data pattern corresponding to the fourth clock signal CK270 may be ‘10011001,’ and the second data pattern corresponding to the fourth clock signal CK270 may be ‘10001000.’

However, the inventive concept is not limited thereto, and in an embodiment, the first data pattern and the second data pattern corresponding to each of the first to fourth clock signals CK0, CK90, CK180, and CK270 may be configured such that a 24-bit pattern is repeated. For example, the first data pattern corresponding to the first clock signal CK0 may be ‘0xFFE000,’ and the second data pattern corresponding to the first clock signal CK0 may be ‘0x7FE000.’

For example, the first data code according to the first data pattern may have a value corresponding to a period between the rising edge and the falling edge of the first clock signal CK0, and may have an unchanged value when the duty cycle of the first clock signal does not change. The second data code according to the second data pattern may have a value corresponding to a period between the rising edge of the second clock signal CK90 and the falling edge of the first clock signal CK0, and may decrease as a phase difference between the first clock signal CK0 and the second clock signal CK90 increases.

Referring again to FIG. 12, in operation S250, a first internal data code may be generated by performing an operation on the first data code and the second data code, a second internal data code may be generated by performing an operation on the third data code and the fourth data code, a third internal data code may be generated by performing an operation on the fifth data code and the sixth data code, and a fourth internal data code may be generated by performing an operation on the seventh data code and the eighth data code. For example, the first internal data code may be generated by performing an operation of subtracting the second data code from the first data code, the second internal data code may be generated by performing an operation of subtracting the fourth data code from the third data code, the third internal data code may be generated by performing an operation of subtracting the sixth data code from the fifth data code, and the fourth internal data code may be generated by performing an operation of subtracting the eighth data code from the seventh data code. Each of the first to fourth internal data codes may increase as a phase difference between the corresponding clock signal and a clock signal ideally having a phase difference of 90 degrees from the corresponding clock signal increases.

In operation S260, a reference data code may be generated by performing an operation on the first to fourth internal data codes. For example, the reference data code may be generated by performing an averaging operation on the first to fourth internal data codes, and may be generated by summing all of the first to fourth internal data codes and dividing the sum by 4.

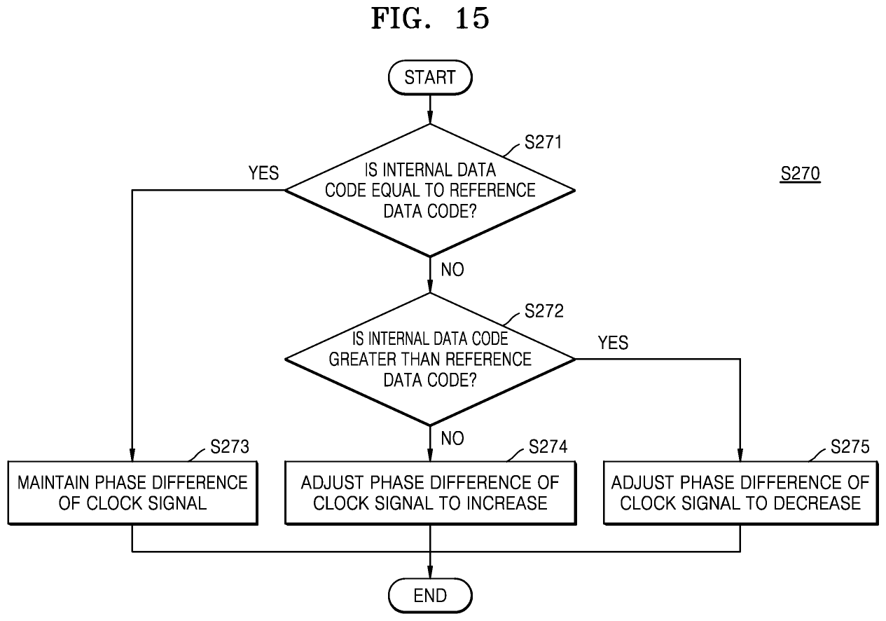

In operation S270, the phase of the first clock signal may be adjusted according to a result of comparing the reference data code with the first internal data code, the phase of the second clock signal may be adjusted according to a result of comparing the reference data code with the second internal data code, the phase of the third clock signal may be adjusted according to a result of comparing the reference data code with the third internal data code, and the phase of the fourth clock signal may be adjusted according to a result of comparing the reference data code with the fourth internal data code. Operation S270 will be described in detail below with reference to FIG. 15.

Referring to FIGS. 12 and 14 together, when the first data pattern corresponding to the first clock signal CK0 is ‘11001100’ and the second data pattern corresponding to the first clock signal CK0 is ‘01000100,’ a code value DC12 of the first data code generated according to a data output signal DO_PP1 of the first data pattern may correspond to the duty cycle of the first clock signal CK0. A code value DC22 of the second data code generated according to a data output signal DO_PP2 of the second data pattern may correspond to a period between the rising edge of the second clock signal CK90 and the falling edge of the first clock signal CK0. The first internal data code may be generated to have a value obtained by subtracting the code value DC22 of the second data code from the code value DC12 of the first data code. Accordingly, the first internal data code may have a greater value as a phase difference between the first clock signal CK0 and the second clock signal CK90 increases.

The same operation may be performed for each of the second clock signal CK90, the third clock signal CK180, and the fourth clock signal CK270 to generate the second to fourth internal data codes. Even when a phase error occurs in each of the first to fourth clock signals CK0, CK90, CK180, and CK270, in the case where no error is present in the duty cycle of each of the first to fourth clock signals CK0, CK90, CK180, and CK270, the sum of all of the first to fourth internal data codes may have a constant value.

Accordingly, by comparing the reference data code with each of the first to fourth internal data codes, the phase errors of the first to fourth clock signals CK0, CK90, CK180, and CK270 may be corrected. The phase errors of the first to fourth clock signals CK0, CK90, CK180, and CK270 may be corrected such that each of the first to fourth internal data codes has the same value as the reference data code.

FIG. 15 is a flowchart illustrating an operating method of a semiconductor device according to the inventive concept. Operation S270 of FIG. 12 may include operations S271 to S275.

Referring to FIG. 15, in operation S271, it may be determined whether an internal data code is equal to the reference data code, and in operation S272, it may be determined whether the internal data code is greater than the reference data code. The internal data code may be one of the first to fourth internal data codes described with reference to FIG. 12. The first internal data code may correspond to a phase difference between the first clock signal and the second clock signal, the second internal data code may correspond to a phase difference between the second clock signal and the third clock signal, the third internal data code may correspond to a phase difference between the third clock signal and the fourth clock signal, and the fourth internal data code may correspond to a phase difference between the fourth clock signal and the first clock signal.

In operation S273, when the internal data code is equal to the reference data code, a phase difference of a clock signal may be maintained. For example, when the first internal data code is equal to the reference data code, the phase difference between the first clock signal and the second clock signal may be maintained.

In operation S275, when the internal data code has a value greater than the reference data code, the phase difference of the clock signal may be adjusted to decrease, and in operation S274, when the internal data code has a value less than the reference data code, the phase difference of the clock signal may be adjusted to increase. For example, when the first internal data code has a value greater than the reference data code, the phase difference between the first clock signal and the second clock signal may be decreased, and when the first internal data code has a value less than the reference data code, the phase difference between the first clock signal and the second clock signal may be increased.

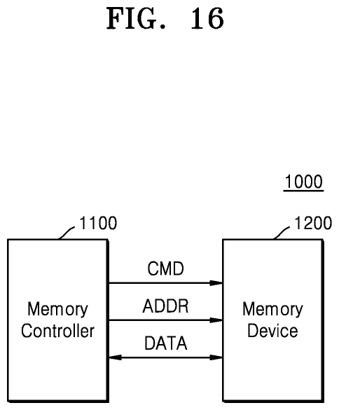

FIG. 16 is a block diagram illustrating a memory system 1000 according to the inventive concept.

Referring to FIG. 16, the memory system 1000 may include a memory controller 1100 and a semiconductor memory device (or a memory device) 1200. The memory system 1000 may further include a plurality of signal lines electrically connecting the memory controller 1100 and the semiconductor memory device 1200 to each other.

The semiconductor memory device 1200 may be controlled by the memory controller 1100. For example, the memory controller 1100 may write data to the semiconductor memory device 1200 or read data from the semiconductor memory device 1200 based on a request from a host (not shown).

The plurality of signal lines may include a command line, an address line, a data line, and/or a power line. The memory controller 1100 may transmit a command CMD and an address ADDR to the semiconductor memory device 1200 through the command line and the address line, may exchange a data signal DATA with the semiconductor memory device 1200 through the data line, and may provide power to the semiconductor memory device 1200 through the power line.

In an embodiment, the memory controller 1100 and the semiconductor memory device 1200 may transmit or exchange data signals in a single-ended scheme.

In an embodiment, the semiconductor memory device 1200 may be a dynamic random-access memory (DRAM). In an embodiment, the memory controller 1100 or the semiconductor memory device 1200 may be the first device 11 described with reference to FIG. 1, and may include the TX circuit 11_1 and the clock calibration circuit 11_2. The TX circuit 11_1 included in the first device 11 may be included in DRAM I/O, etc.

Alternatively, the memory system 1000 may further include a buffer die that is connected to a plurality of semiconductor memory devices and performs an interface operation for providing the data signal DATA, the command CMD, the address ADDR, etc. received from the memory controller 1100 to the plurality of semiconductor memory devices, or for providing the data signal DATA received from the plurality of semiconductor memory devices to the memory controller 1100. The buffer die may include a physical layer, which is an interface circuit, to perform such an interface operation, and the TX circuit (e.g., 11_1 in FIG. 1) included in the first device 11 may be included in the physical layer.

While the inventive concept has been particularly shown and described with reference to embodiments thereof, it will be understood that various changes in form and details may be made therein without departing from the spirit and scope of the present invention as set forth in the following claims.

The ordinal expressions, such as ‘first’, ‘second’, ‘third’, and ‘fourth’, used in the specification may modify various components regardless of a sequence and/or significance and are only used to distinguish one component from other components without limiting the components. For example, a first user device and a second user device may indicate different user devices regardless of a sequence or significance. For example, without departing from the right scope described in the specification, a first component may be named a second component, and similarly, the second component may also be named the first component. First components in the specification may be named a first component, a second component, a third component, a fourth component, a fifth component, a sixth component, and the like, and second components in the specification may be named a first component, a second component, a third component, and the like.

What is claimed is:

1. A semiconductor device comprising:
at least one transmission circuit configured to receive clock signals and transmit a data output signal; and
a clock calibration circuit configured to convert the data output signal into a data code corresponding to an average level of the data output signal and generate a control signal,
wherein the at least one transmission circuit comprises:
a clock correcting circuit configured to adjust a duty cycle or a phase difference of each of the clock signals in response to the control signal and generate corrected clock signals; and
a pattern generating circuit configured to generate data of a pre-designated test pattern for a calibration operation of the clock calibration circuit.

2. The semiconductor device of claim 1, wherein the at least one transmission circuit is further configured to transmit the data output signal in a single-ended scheme.

3. The semiconductor device of claim 1, wherein the clock calibration circuit comprises:
a low-pass filter configured to generate a data signal by filtering the data output signal;
an analog-to-digital conversion circuit configured to convert the data signal into the data code; and
a clock correcting controller configured to generate the control signal based on the data code.

4. The semiconductor device of claim 3, wherein the clock correcting controller is further configured to transmit a signal for the pre-designated test pattern to the pattern generating circuit, and
wherein the pattern generating circuit is configured to generate the data based on the transmitted signal.

5. The semiconductor device of claim 1, wherein the at least one transmission circuit further comprises:
a serializer configured to serialize, based on the corrected clock signals, the data generated from the pattern generating circuit; and
a transmission driver configured to generate the data output signal based on the serialized data and transmit the data output signal through a channel.

6. The semiconductor device of claim 5, wherein the serializer comprises a 4:1 multiplexer configured to operate based on the corrected clock signals, and
wherein the corrected clock signals comprise first to fourth corrected clock signals having a phase difference of 90 degrees from one another.

7. The semiconductor device of claim 1, wherein the at least one transmission circuit further comprises a switching circuit configured to transmit the data output signal to the clock calibration circuit.

8. The semiconductor device of claim 7, wherein the at least one transmission circuit comprises a first transmission circuit and a second transmission circuit, and
wherein the clock calibration circuit is further configured to:
receive a first data output signal as the data output signal from the first transmission circuit and transmit a first control signal as the control signal to the first transmission circuit, and
receive a second data output signal as the data output signal from the second transmission circuit and transmit a second control signal as the control signal to the second transmission circuit.

9. The semiconductor device of claim 1, wherein the pattern generating circuit is further configured to generate first data of a first data pattern and second data of a second data pattern for the calibration operation,
wherein the clock calibration circuit is further configured to generate, according to the first data, a first data code that is linearly proportional to an amount of change in a duty cycle of a target clock signal, and generate, according to the second data, a second data code that is linearly proportional to the amount of change in the duty cycle of the target clock signal, and
wherein the clock correcting circuit is further configured to adjust the duty cycle of the target clock signal among the clock signals.

10. The semiconductor device of claim 9, wherein the clock signals comprise first to fourth clock signals, and
wherein the first data corresponding to the second clock signal has a pattern delayed by integer multiple a unit interval of the data output signal from the first data corresponding to the first clock signal.

11. The semiconductor device of claim 1, wherein the pattern generating circuit is further configured to generate first data of a first data pattern and second data of a second data pattern for the calibration operation,
wherein the clock calibration circuit is further configured to generate a first data code according to the first data and a second data code according to the second data,
wherein the clock correcting circuit is further configured to adjust a phase difference between the clock signals, and
wherein a difference value between the first data code and the second data code is proportional to the phase difference.

12. The semiconductor device of claim 11, wherein the clock signals comprise first to fourth clock signals,
wherein the first data corresponding to the second clock signal has a pattern delayed by integer multiple a unit interval of the data output signal from the first data corresponding to the first clock signal.

13. An operating method of a semiconductor device, the operating method comprising:
generating a first data code and a second data code according to respective average levels of a data output signal of a first data pattern corresponding to a first clock signal and a data output signal of a second data pattern corresponding to the first clock signal;
generating a first reference data code by performing an operation on the first data code and the second data code; and
adjusting a duty cycle of the first clock signal according to a result of comparing the first reference data code with the second data code.

14. The operating method of claim 13, wherein the generating of the first data code and the second data code comprises generating the first data code that is linearly proportional to an amount of change in the duty cycle of the first clock signal, and generating the second data code that is linearly proportional to the amount of change in the duty cycle of the first clock signal,
wherein the generating of the first reference data code comprises generating the first reference data code that is linearly inversely proportional to the amount of change in the duty cycle of the first clock signal, and
wherein the adjusting of the duty cycle of the first clock signal comprises:
maintaining the duty cycle of the first clock signal when a value of the second data code is equal to a value of the first reference data code;
adjusting the duty cycle of the first clock signal to decrease when the value of the second data code is greater than the value of the first reference data code; and
adjusting the duty cycle of the first clock signal to increase when the value of the second data code is less than the value of the first reference data code.

15. The operating method of claim 13, further comprising:
when a lowest voltage level of each of the data output signal of the first data pattern and the data output signal of the second data pattern is not 0, generating a start data code according to an average level of a data output signal of a start data pattern,
wherein the generating of the first reference data code comprises generating the first reference data code by performing an operation on the start data code, the first data code, and the second data code.

16. The operating method of claim 15, wherein the generating of the first reference data code further comprises generating the first reference data code having a value obtained by subtracting twice a code value of the second data code from a code value of the first data code and adding twice a code value of the start data code to a result of the subtraction.

17. The operating method of claim 13, further comprising:
generating a third data code and a fourth data code by low-pass filtering and analog-to-digital converting a data output signal of a first data pattern corresponding to a second clock signal and a data output signal of a second data pattern corresponding to the second clock signal, respectively;
generating a second reference data code by performing an operation on the third data code and the fourth data code; and
adjusting a duty cycle of the second clock signal according to a result of comparing the second reference data code with the fourth data code,
wherein the first clock signal and the second clock signal have different phases from each other.

18. An operating method of a semiconductor device that generates a data output signal according to first to fourth clock signals having different phases from one another, the operating method comprising:
generating a first data code and a second data code according to respective average levels of a data output signal of a first data pattern corresponding to the first clock signal and a data output signal of a second data pattern corresponding to the first clock signal;
generating a third data code and a fourth data code according to respective average levels of a data output signal of a first data pattern corresponding to the second clock signal and a data output signal of a second data pattern corresponding to the second clock signal;
generating a fifth data code and a sixth data code according to respective average levels of a data output signal of a first data pattern corresponding to the third clock signal and a data output signal of a second data pattern corresponding to the third clock signal;
generating a seventh data code and an eighth data code according to respective average levels of a data output signal of a first data pattern corresponding to the fourth clock signal and a data output signal of a second data pattern corresponding to the fourth clock signal;
generating a first internal data code by performing an operation on the first data code and the second data code;
generating a second internal data code by performing an operation on the third data code and the fourth data code;
generating a third internal data code by performing an operation on the fifth data code and the sixth data code;
generating a fourth internal data code by performing an operation on the seventh data code and the eighth data code;
generating a reference data code by performing an operation on the first to fourth internal data codes;
adjusting the phase of the first clock signal according to a result of comparing the reference data code with the first internal data code;
adjusting the phase of the second clock signal according to a result of comparing the reference data code with the second internal data code;
adjusting the phase of the third clock signal according to a result of comparing the reference data code with the third internal data code; and
adjusting the phase of the fourth clock signal according to a result of comparing the reference data code with the fourth internal data code.

19. The operating method of claim 18, wherein the generating of the first to fourth internal data codes comprises:
generating the first internal data code having a value obtained by subtracting a value of the second data code from a value of the first data code;
generating the second internal data code having a value obtained by subtracting a value of the fourth data code from a value of the third data code;
generating the third internal data code having a value obtained by subtracting a value of the sixth data code from a value of the fifth data code; and
generating the fourth internal data code having a value obtained by subtracting a value of the eighth data code from a value of the seventh data code, and wherein:
the value of the first internal data code corresponds to a phase difference between the first clock signal and the second clock signal,
the value of the second internal data code corresponds to a phase difference between the second clock signal and the third clock signal,
the value of the third internal data code corresponds to a phase difference between the third clock signal and the fourth clock signal, and
the value of the fourth internal data code corresponds to a phase difference between the fourth clock signal and the first clock signal.

20. The operating method of claim 19, wherein the generating of the reference data code comprises generating the reference data code having an average value of the values of the first to fourth internal data codes.
